(19) United States
(12) Patent Application Publication
(10) Pub. No.: US 2006/0240678 A1
(43) Pub. Date: Oct. 26, 2006

(54) Method of forming a LP-CVD oxide film without oxidizing an underlying metal film

(75) Inventors: Min Sik Jang, Icheon-Si (KR); Dong Ho Lee, Seongnam-Si (KR); Eun-Shil Park, Namyangju-Si (KR); Kwang Seok Jeon, Yongin-Si (KR); Seung Woo Shin, Kyeongki-Do (KR); Choon Kun Ryu, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-shi (KR)

(21) Appl. No.: 11/155,261

(22) Filed: Jun. 17, 2005

(30) Foreign Application Priority Data
Apr. 22, 2005 (KR) 2005-33706

(51) Int. Cl. H01L 21/31; H01L 21/469

(52) U.S. Cl. 438/770

(57) ABSTRACT

A method of manufacturing a semiconductor device includes forming a LP-CVD oxide film on sides of a gate including a metal film by means of a LP-CVD method that does not cause oxidization of the metal film. Oxidization of a metal film can be prevented physically, and degradation of the electrical device characteristics can be prevented.

### BACKGROUND

1. Technical Field

A method of manufacturing a semiconductor device that includes forming a LP-CVD oxide film formation with causing oxidation of an underlying method film thereby improving the physical and electrical properties of the devices can be improved.

2. Disclosure of the Related Art

As the level of integration of semiconductor devices continues to increase and the line width of circuits becomes smaller, there is a need to form a gate using materials having low resistance so as to improve the speed of devices.

Recently, tungsten (W) that has been widely used as a gate material. While tungsten (W) is advantageous in reducing resistance of a gate compared to an existing tungsten silicide (WSiₓ), tungsten also has several disadvantages.

One problem is that tungsten (W) is likely to be abnormally oxidized in a subsequent thermal process, and a thermal treatment process or a deposition process including an oxide material.

Specifically, after a gate is formed, an insulating film serving as a buffer or sidewall has to be formed. An oxide film that is formed by means of a typical low-pressure chemical vapor deposition (LP-CVD) method cannot be deposited without abnormal oxidization of the tungsten.

In order to prevent the tungsten from being oxidized, a method of depositing a LP-CVD nitride film using the LP-CVD method, a method of depositing an atomic layer deposition (ALD) oxide film at low temperature using atomic layer deposition (ALD) method have been used.

While these techniques can be implemented because they do not cause oxidization of tungsten, however, the LP-CVD nitride film has a problem in that electrical properties of a device are degraded from the influence of hydrogen contained in the film quality or stress. Further, the ALD oxide film has a problem in that electrical properties of a device are degraded from the influence of a catalyst, which is used in forming the ALD oxide film, and carbon and chlorine contained in a source gas.

In view of the above, there is a need for an alternate material, which can prevent oxidization of tungsten from a physical viewpoint and which does not degrade the properties of a device from an electrical viewpoint.

### SUMMARY OF THE DISCLOSURE

A method of manufacturing a semiconductor device is disclosed wherein oxidization of an underlying tungsten layer is avoided and degradation of electrical properties of the device can be prevented.

A disclosed method of manufacturing a semiconductor device comprises: forming a gate including a metal film on a predetermined region of a semiconductor substrate, and forming a LP-CVD oxide film on the entire surface by means of a LP-CVD method that does not cause oxidization of the metal film.

The gate is preferably formed using a single film of a metal film.

The metal film is preferably a tungsten film.

The gate is preferably formed using a stack film of a polysilicon film and a metal film.

The metal film is preferably a tungsten film.

An anti-silicide film for prohibiting silicide reaction between the polysilicon film and the metal film between the polysilicon film and the metal film can be further formed.

The anti-silicide film can be one of WNₓ, TiN and WSiₓ.

The method can further include forming a selective oxide film by means of a selective oxidization process that oxidizes the surface of polysilicon in a material constituting the semiconductor substrate and the gate, without oxidizing the metal film before the LP-CVD oxide film is formed.

The selective oxidization process is preferably performed through control of the ratio of H₂ and H₂O under a H₂ atmosphere.

The selective oxidization process can be performed using plasma mode.

The selective oxidization process is preferably performed at a temperature in the range of from about 600 to about 1000° C.

The method can further include the step of performing thermal treatment under a nitrogen- or argon-based gas atmosphere before the LP-CVD oxide film is formed.

The method can further include forming a selective oxide film by oxidizing the surface of polysilicon in a material constituting the semiconductor substrate and the gate without oxidizing the metal film after the LP-CVD film is formed.

The selective oxidization process is preferably performed through control of the ratio of H₂ and H₂O under a H₂ atmosphere.

The selective oxidization process is preferably performed using plasma mode.

The selective oxidization process is preferably performed at a temperature in the range of about 600 to about 1000° C.

The method can further include performing thermal treatment under a nitrogen- or argon-based gas atmosphere after the LP-CVD oxide film is formed.

The LP-CVD film forming can include loading the semiconductor substrate on which the gate is formed into a LP-CVD apparatus from which an oxygen gas is removed, stabilizing a temperature of the LP-CVD apparatus to a temperature for depositing the oxide film, and flowing an oxygen source gas and a silicon source gas to form the LP-CVD oxide film.

The loading of the semiconductor substrate is preferably carried out at a temperature from about 25 to about 400° C. where the metal film is not oxidized.

The temperature for depositing the oxide film is preferably in the range of from about 600 to about 1000° C.

The oxygen gas within the LP-CVD apparatus can be removed by purging and pumping nitrogen gas into the apparatus.

The purge and pumping of the nitrogen gas can be performing using a N₂ purge box or a load lock apparatus.

The oxygen source gas can be flowed first, followed by the silicon source gas.

The oxygen source gas and the silicon source gas can also be flowed simultaneously.

The oxygen source gas is preferably N₂O and the silicon source gas is preferably monosilane (SiH₄) and dichlorosilane (SiH₂Cl₂).

A pressure when forming the LP-CVD oxide film is preferably set to a range from about 1 m Torr to about 10 Torr.

### BRIEF DESCRIPTION OF THE DRAWINGS

FIGS. 1a to 1c are cross-sectional views for explaining a first disclosed method of manufacturing a semiconductor device;

FIGS. 2a to 2c are cross-sectional views for explaining a second disclosed method of manufacturing a semiconductor device;

FIGS. 3a to 3c are cross-sectional views for explaining a third disclosed method of manufacturing a semiconductor device; and

FIG. 4 is a view illustrating comparison results of XRD analysis in the case where an oxide film is formed by means of a prior LP-CVD method and the case where an oxide film is formed by means of a disclosed LP-CVD method.

### DETAILED DESCRIPTION OF THE PRESENTLY PREFERRED EMBODIMENTS

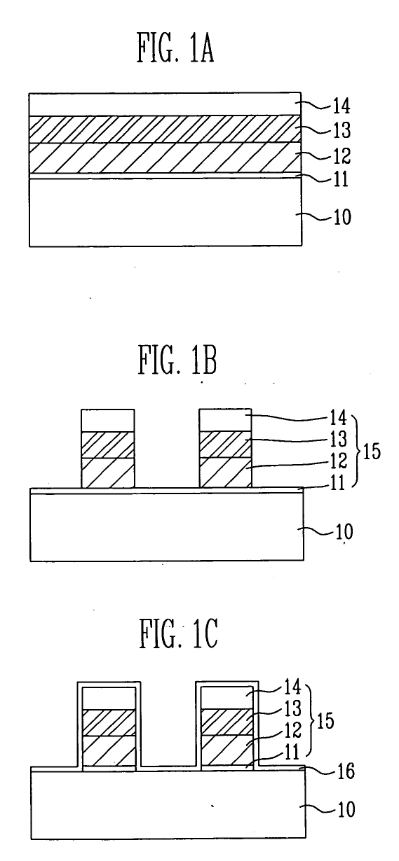

FIGS. 1a to 1c are cross-sectional views for explaining a first disclosed method of manufacturing a semiconductor device. Referring first to FIG. 1a, a gate dielectric film 11 and a polysilicon film 12 are formed on a semiconductor substrate 10. A metal film such as a tungsten film 13 is formed on the polysilicon film 12.

The polysilicon film 12 and the tungsten film 13 are gate electrodes, which can be formed using only the tungsten film 13 without forming the polysilicon film 12. Further, in order to prevent tungsten silicide (WSiₓ,) from being formed due to reaction of the polysilicon film 12 and the tungsten film 13, an anti-silicide film, such as WNₓ, TiN or WSiₓ, can be added at the interface of the polysilicon film 12 and the tungsten film 13.

A hard mask film 14 is then formed on the tungsten film 13. Referring to FIG. 1b, the hard mask film 14 is patterned by means of a photolithography and etch process. The tungsten film 13, the polysilicon film 12 and the gate dielectric film 11 are etched using the patterned hard mask film 14 to form a gate 15.

As shown in FIG. 1c, a LP-CVD oxide film 16 is formed on the entire surface of the semiconductor substrate 10, including the gate 15, by means of a LP-CVD method that does not generate oxidization of the tungsten film 13.

At this time, the LP-CVD oxide film 16 can be formed using a batch type LP-CVD apparatus or a single wafer processing LP-CVD apparatus. The manufacturing method for the LP-CVD oxide films 16 depend upon each apparatus is as follows.

First, in the case where the batch type apparatus is used, a nitrogen-based gas is flowed into a furnace of the batch type apparatus at low temperature of 25 to 400° C. where oxidization of tungsten is not generated, thus removing an oxygen gas within the furnace. In order to flow the nitrogen-based gas, a N₂ purge box or a load lock apparatus can be used.

The semiconductor substrate 10 in which the gate 15 is formed is then loaded into the furnace. If loading is completed, a temperature within the furnace is increased to 600 to 1000° C. for deposition of an oxide film. The LP-CVD oxide film 16 that does not generate abnormal oxidization of the tungsten film 13 is formed by flowing N₂O being an oxygen source gas and monosilane (SiH₄) and dichlorosilane (SiH₂Cl₂) being a silicon source gas at a low pressure state of 1m Torr to 10 Torr.

A method of flowing the source gas can include a method in which N₂O being an oxygen source gas is first flowed and SiH₄ and SiH₂Cl₂ being a silicon source gas are then flowed, or a method in which N₂O and SiH₄ and SiH₂Cl₂ are flowed at the same time.

When a single wafer processing apparatus is used, an oxygen gas within a cassette loading unit onto which a plurality of the semiconductor substrates 10 is loaded by means of a load lock apparatus is removed, an oxygen gas within a transfer unit from the cassette loading unit to a chamber is removed using a purge gas, and an oxygen gas within the chamber is removed by flowing a nitrogen-based gas.

The temperature within the chamber is then stabilized to a temperature in the range of from about 600 to about 1000° C., which is the deposition temperature of the oxide film. The LP-CVD oxide film 16 that does not generate abnormal oxidization of the tungsten film 13 is then formed by flowing N₂O being an oxygen source gas and SiH₄ and SiH₂Cl₂ being a silicon source gas at a pressure of 1 mTorr to 500 Torr.

A method of flowing the source gas can include a method in which N₂O being an oxygen source gas is first flowed and SiH₄ and SiH₂Cl₂ being a silicon source gas are then flowed, or a method in which N₂O and SiH₄ and SiH₂Cl₂ are flowed at the same time.

In the event that sealing of a tungsten film and a spacer are formed at the same time using a LP-CVD oxide film of the present invention without forming a gate spacer separately, the spacer is formed by etching back the LP-CVD oxide film 16 so that the LP-CVD oxide film 16 remains at both sides of the gate 15. In this case, a thickness of the LP-CVD oxide film 16 is not specially limited.

Meanwhile, in the case where the gate spacer is formed using a nitride film, the LP-CVD oxide film 16 serves as a buffer between the gate 15 and the nitride film spacer. In this case, the LP-CVD oxide film 16 is preferably formed to a thickness in the range of from about 10 to about 50 Å.

Fabrication of the semiconductor device according to a first disclosed method is thereby completed.

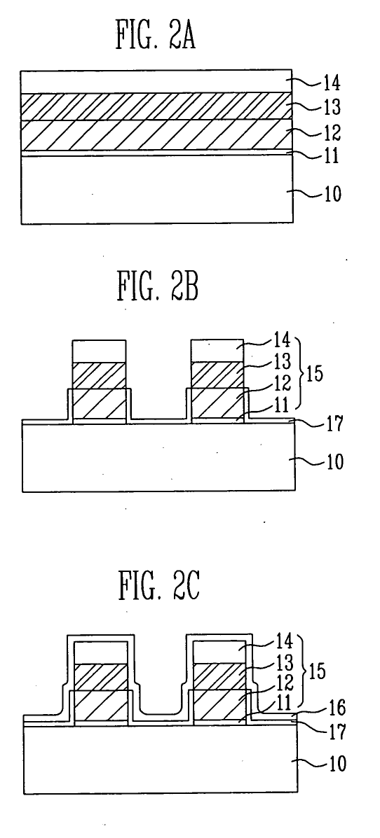

FIGS. 2a to 2care cross-sectional views for explaining a second disclosed method of manufacturing a semiconductor device. The second disclosed method is the same as the first method except that a selective oxidization process or a thermal process is added after the process of forming the gate in order to mitigate etch damage upon gate etching and provide stable electrical properties.

Referring to FIG. 2a, a gate dielectric film 11 and a polysilicon film 12 are formed on a semiconductor substrate 10. A metal film such as a tungsten film 13 is formed on the polysilicon film 12. The polysilicon film 12 and the tungsten film 13 are gate electrodes, which can be formed using only the tungsten film 13 without forming the polysilicon film 12. Further, in order to prevent tungsten silicide (WSiₓ,) from being formed due to reaction of the polysilicon film 12 and the tungsten film 13, an anti-silicide film, such as WNx, TiN or WSiₓ, can be added at the interface of the polysilicon film 12 and the tungsten film 13.

A hard mask film 14 is then formed on the tungsten film 13. Referring to FIG. 2b, the hard mask film 14 is patterned by means of a photolithography and etch process. The tungsten film 13, the polysilicon film 12 and the gate dielectric film 11 are etched using the patterned hard mask film 14 to form a gate 15.

Thereafter, in order to mitigate etch damage due to a gate etch process and to secure stabilized electrical properties, a selective oxide film 17 is formed on the sides of the polysilicon film 12 and on the semiconductor substrate 10 under a H₂ atmosphere having a temperature in the range of from about 600 to about 1000° C. and through control of the ratio of H₂ and H₂O in such a manner that the tungsten film 13 is not oxidized but only the polysilicon film 12 and the semiconductor substrate 10 are selectively oxidized by means of a selective oxidization process. In the selective oxidization process, a plasma mode can be used instead of controlling the ratio of H₂ and H₂O. Meanwhile, a thermal treatment process using a nitrogen gas and an argon gas can be used instead of the selective oxidization process.

Referring next to FIG. 2c, a LP-CVD oxide film 16 is formed on the entire surface of the semiconductor substrate 10, including the gate 15, by means of a LP-CVD method that does not generate oxidization of the tungsten film 13.

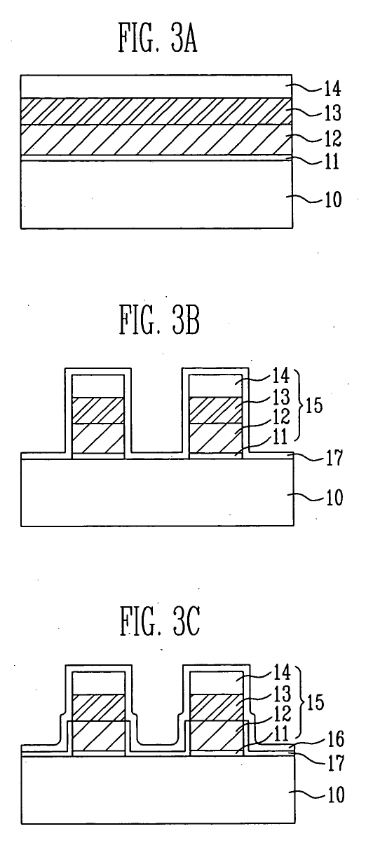

FIGS. 3a to 3c are cross-sectional views for explaining a third disclosed method of manufacturing a semiconductor device. The third disclosed method is the same as the first method except that a selective oxidization process or a thermal treatment process is added after formation of the LP-CVD oxide film 16 in order to mitigate etch damage upon etching of the gate 15 and provide stabilized electrical properties.

Referring to FIG. 3a, a gate dielectric film 11 and a polysilicon film 12 are formed on a semiconductor substrate 10. A metal film such as a tungsten film 13 is formed on the polysilicon film 12.

The polysilicon film 12 and the tungsten film 13 are gate electrodes, which can be formed using only the tungsten film 13 without forming the polysilicon film 12. Further, in order to prevent tungsten silicide (WSiₓ) from being formed due to reaction of the polysilicon film 12 and the tungsten film 13, an anti-silicide film, such as WNx, TiN or WSiₓ, can be added at the interface of the polysilicon film 12 and the tungsten film 13.

A hard mask film 14 is then formed on the tungsten film 13.

Referring to FIG. 3b, the hard mask film 14 is patterned by means of a photolithography and etch process. The tungsten film 13, the polysilicon film 12 and the gate dielectric film 11 are etched using the patterned hard mask film 14 to form a gate 15.

A LP-CVD oxide film 16 is then formed on the entire surface of the semiconductor substrate 10, including the gate 15, by means of a LP-CVD method that does not generate oxidization of the tungsten film 13.

The method of forming the LP-CVD oxide film 16 by means of the LP-CVD method that does not generate oxidization of the tungsten film 13 is the same as that described in the first embodiment.

Referring next to FIG. 3c, in order to mitigate etch damage due to a gate etch process and to secure stable electrical properties, a selective oxide film 17 is formed on the sides of the polysilicon film 12 and on the semiconductor substrate 10 under a H₂ atmosphere having a temperature in the range of from about 600 to abut 1000° C. and through control of the ratio of H₂ and H₂O in such a manner that the tungsten film 13 is not oxidized but only the polysilicon film 12 and the semiconductor substrate 10 are selectively oxidized by means of a selective oxidization process. In the selective oxidization process, a plasma mode can be used instead of controlling the ratio of H₂ and H₂O.

Meanwhile, a thermal treatment process using a nitrogen gas and an argon gas can be used instead of the selective oxidization process. Fabrication of the semiconductor device according to the third method is thereby completed.

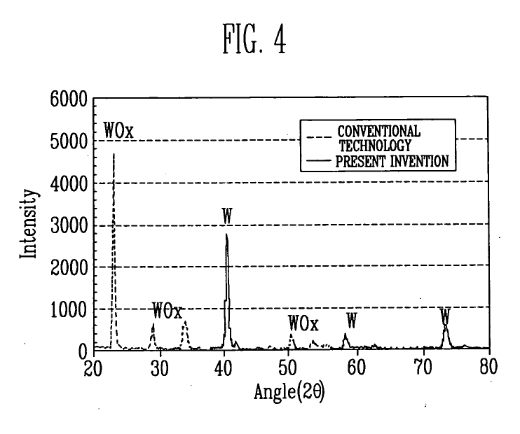

FIG. 4 is a view illustrating comparison results of XRD analysis in the case where an oxide film is formed by means of an existing LP-CVD method and a case where an oxide film is formed by means of a disclosed LP-CVD method.

From FIG. 4, it can be seen that tungsten is all oxidized when an oxide film is deposited by means of an existing LP-CVD method, but the tungsten film is never oxidized when the oxide film is deposited by means of the disclosed LP-CVD method.

As described above, according to this disclosure, when forming an insulating film on sides of a gate, a LP-CVD method that does not generate oxidization of a metal film is used. Accordingly, the disclosed methods are advantageous in that oxidization of a metal film can be prevented from a physical viewpoint and degradation of device characteristics can be prevented from an electrical viewpoint.

What is claimed is:

1. A method of manufacturing a semiconductor device comprising:
forming a gate comprising a metal film on a predetermined region of a semiconductor substrate; and
forming a LP-CVD oxide film on the entire surface by means of a LP-CVD method that does not cause oxidization of the metal film.

2. The method as claimed in claim 1, wherein the metal film of the gate is the only metal film of the gate.

3. The method as claimed in claim 2, wherein the metal film is a tungsten film.

4. The method as claimed in claim 1, wherein the gate comprises a stack film of a polysilicon film and the metal film.

5. The method as claimed in claim 4, wherein the metal film is a tungsten film.

6. The method as claimed in claim 4, further comprising forming an anti-silicide film between the polysilicon film and the metal film for prohibiting silicide reaction between the polysilicon film and the metal film.

7. The method as claimed in claim 6, wherein the anti-silicide film is selected from the group consisting of WNₓ, TiN and WSiₓ.

8. The method as claimed in claim 1, further comprising, before the LP-CVD oxide film is formed, forming a selective oxide film on sides of the gate and on the substrate by means of a selective oxidization process that oxidizes silicon surfaces that constitute the semiconductor substrate and the gate and without oxidizing the metal film.

9. The method as claimed in claim 8, wherein the selective oxidization process is performed through controlling a ratio of H₂ and H₂O under a H₂ atmosphere.

10. The method as claimed in claim 8, wherein the selective oxidization process is performed using a plasma mode.

11. The method as claimed in claim 8, wherein the selective oxidization process is performed at a temperature in a range of from about 600 to about 1000° C.

12. The method as claimed in claim 1, further performing a thermal treatment under a nitrogen or an argon-based atmosphere after the gate is formed and before the LP-CVD oxide film is formed.

13. The method as claimed in claim 1, further comprising, after the LP-CVD film is formed, forming a selective oxide film on sides of the gate and on the substrate by oxidizing silicon surfaces constituting the semiconductor substrate and the gate without oxidizing the metal film.

14. The method as claimed in claim 13, wherein the selective oxidization process is performed by controlling of a ratio of H₂ and H₂O under a H₂ atmosphere.

15. The method as claimed in claim 13, wherein the selective oxidization process is performed using a plasma mode.

16. The method as claimed in claim 13, wherein the selective oxidization process is performed at a temperature in a range of from about 600 to about 1000° C.

17. The method as claimed in claim 1, further including the step of performing a thermal treatment under a nitrogen or an argon-based gas atmosphere after the formation of the LP-CVD oxide layer.

18. The method as claimed in claim 1, wherein the forming of the LP-CVD oxide layer comprises:
loading the semiconductor substrate on which the gate has been formed into a LP-CVD apparatus from which oxygen has been removed;
stabilizing a temperature of the LP-CVD apparatus to a temperature for depositing the oxide film; and
flowing an oxygen source gas and a silicon source gas into the apparatus to form the LP-CVD oxide film.

19. The method as claimed in claim 18, wherein the loading of the semiconductor substrate is carried out at a temperature in a range of from about 25 to about 400° C. so that the metal film is not oxidized.

20. The method as claimed in claim 18, wherein the temperature for depositing the oxide film is in the range of from about 600 to about 1000° C.

21. The method as claimed in claim 18, wherein the oxygen gas within the LP-CVD apparatus is removed by purging and pumping nitrogen gas into the apparatus.

22. The method as claimed in claim 21, wherein the purge and pumping of nitrogen is performed using one of a N₂ purge box or a load lock apparatus.

23. The method as claimed in claim 18, wherein the oxygen source gas is first flowed before the silicon source gas is flowed.

24. The method as claimed in claim 18, wherein the oxygen source gas and the silicon source gas are flowed simultaneously.

25. The method as claimed in claim 18, wherein the oxygen source gas is N₂O and the silicon source gas is a combination of SiH₄ and SiH₂Cl₂.

26. The method as claimed in claim 18, wherein a pressure when forming the LP-CVD oxide film is set to a range of about 1 m Torr to about 10 Torr.
